(19) United States
(12) Patent Application Publication
(10) Pub. No.: US 2025/0063920 A1
(43) Pub. Date: Feb. 20, 2025

(54) DISPLAY DEVICE

(71) Applicant: Sharp Display Technology Corporation, Kameyama City, Mie (JP)

(72) Inventors: Tohru OKABE, Kameyama City (JP); Shoji OKAZAKI, Kameyama City (JP); Shinsuke SAIDA, Kameyama City (JP); Shinji ICHIKAWA, Kameyama City (JP); Hiroki TANIYAMA, Kameyama City (JP); Eiji FUJIMOTO, Kameyama City (JP)

(21) Appl. No.: 18/722,442

(22) PCT Filed: Feb. 24, 2022
(86) PCT No.: PCT/JP2022/007626

§ 371 Date: Jun. 20, 2024

(51) Int. Cl. H10K 59/80; H10K 59/131; H10K 77/10; H10K 102/00

(52) U.S. Cl. CPC H10K 59/8722; H10K 59/131; H10K 77/111; H10K 2102/311; H10K 2102/341

(57) ABSTRACT

A display device includes: a thin film transistor layer including a first inorganic insulating film, a first metal layer, a second inorganic insulating film, a second metal layer, and a flattening resin film layered in order; and a light-emitting element layer. A slit is provided in the first and second inorganic insulating film in a bending portion. A filled resin film fills the slit. On the filled resin film, a plurality of lead wiring lines are provided in the same layer as the second metal layer. At least one lead wiring lines is electrically connected to a first and second lower wiring line provided in the same layer as the first metal layer and extending to a display region side and a terminal portion side via a first and second contact hole formed in a layered film including the second inorganic insulating film and the filled resin film.

### TECHNICAL FIELD

The disclosure relates to a display device.

### BACKGROUND ART

In recent years, as a display device replacing a liquid crystal display device, a self-luminous organic electroluminescence (hereinafter also referred to as “EL”) display device using an organic EL element has attracted attention. For this organic EL display device, a flexible organic EL display device in which an organic EL element or the like is formed on a resin substrate having flexibility has been proposed. Here, in the organic EL display device, there is provided a frame region surrounding a rectangular display region for displaying an image, and reduction of the frame region is demanded. Additionally, with the flexible organic EL display device, for example, reducing the frame region by bending the frame region on the terminal portion side on which a plurality of terminals are arrayed has been proposed.

For example, PTL 1 discloses a flexible display device in which a bending hole is formed, and accordingly a part of each of a buffer film, a gate insulating film, and an interlayer insulating film corresponding to a bending region is removed and disconnection of a wiring line is prevented from occurring.

### CITATION LIST

### Patent Literature

PTL 1: JP 2014-232300 A

### SUMMARY

### Technical Problem

In the flexible organic EL display device, inorganic insulating films such as a base coat film, a gate insulating film, and an interlayer insulating film are provided on a resin substrate. Therefore, in order to suppress disconnection of a plurality of lead wiring lines placed in the frame region, a structure has been proposed in which the inorganic insulating films in a portion to be bent (bending portion) in the frame region are removed, the removed portion is filled with a resin film, and the lead wiring lines are formed on the resin film. However, even when the inorganic insulating films are removed from the bending portion, the removed portion is filled with the resin film, and the lead wiring lines are formed on the filled resin film, residues of the metal film serving as the lead wiring line may be generated at steps at both end portions of the filled resin film provided in a belt shape, and the residue may cause a short circuit between the adjacent lead wiring lines.

The disclosure has been made in view of the above, and an object of the disclosure is to suppress a short circuit between adjacent lead wiring lines in the bending portion.

### Solution to Problem

In order to achieve the object described above, a display device according to the disclosure includes a resin substrate, a thin film transistor layer provided on the resin substrate and including a first inorganic insulating film, a first metal layer, a second inorganic insulating film, a second metal layer, and a flattening resin film layered in order, and a light-emitting element layer provided on the thin film transistor layer and including a plurality of first electrodes, a plurality of light-emitting function layers, and a common second electrode layered in order, corresponding to a plurality of subpixels constituting a display region, in which a frame region is provided around the display region, a terminal portion is provided in an end portion of the frame region, a bending portion is provided between the display region and the terminal portion and extends in one direction, a slit is provided in the first inorganic insulating film and the second inorganic insulating film in the bending portion and extends along an extending direction of the bending portion, a filled resin film is provided in the bending portion in a belt shape and fills the slit, on the filled resin film, a plurality of lead wiring lines are provided in the same layer using the same material as the second metal layer and extends parallel to each other in a direction intersecting the extending direction of the bending portion, and at least one of the plurality of lead wiring lines is electrically connected to a first lower wiring line and a second lower wiring line provided in the same layer using the same material as the first metal layer and extending to a display region side and a terminal portion side via a first contact hole and a second contact hole formed in a layered film including the second inorganic insulating film and the filled resin film on the display region side and the terminal portion side, respectively.

### Advantageous Effects of Disclosure

According to the disclosure, it is possible to suppress a short circuit between adjacent lead wiring lines in a bending portion.

### BRIEF DESCRIPTION OF DRAWINGS

FIG. 1 is a plan view illustrating a schematic configuration of an organic EL display device according to a first embodiment of the disclosure.

FIG. 2 is a plan view of a display region of the organic EL display device according to the first embodiment of the disclosure.

FIG. 3 is a cross-sectional view of the organic EL display device taken along a line III-III in FIG. 1.

FIG. 4 is an equivalent circuit diagram of a thin film transistor layer included in the organic EL display device according to the first embodiment of the disclosure.

FIG. 5 is a cross-sectional view of an organic EL layer constituting the organic EL display device according to the first embodiment of the disclosure.

FIG. 6 is a cross-sectional view of a frame region of the organic EL display device taken along a line VI-VI in FIG. 1.

FIG. 7 is a plan view of the frame region including a bending portion of the organic EL display device according to the first embodiment of the disclosure.

FIG. 8 is a cross-sectional view of the frame region of the organic EL display device taken along a line VIII-VIII in FIG. 7.

FIG. 9 is a plan view of a frame region including a bending portion of an organic EL display device according to a second embodiment of the disclosure.

FIG. 10 is a cross-sectional view of the frame region of the organic EL display device taken along a line X-X in FIG. 9.

FIG. 11 is a cross-sectional view of the frame region of the organic EL display device taken along a line XI-XI in FIG. 9.

FIG. 12 is a plan view of a frame region including a bending portion of an organic EL display device according to a third embodiment of the disclosure.

FIG. 13 is a plan view of a frame region including a bending portion of an organic EL display device according to a fourth embodiment of the disclosure.

### DESCRIPTION OF EMBODIMENTS

Embodiments of a technique according to the disclosure will be described below in detail with reference to the drawings. Note that the technique according to the disclosure is not limited to the embodiments to be described below.

### First Embodiment

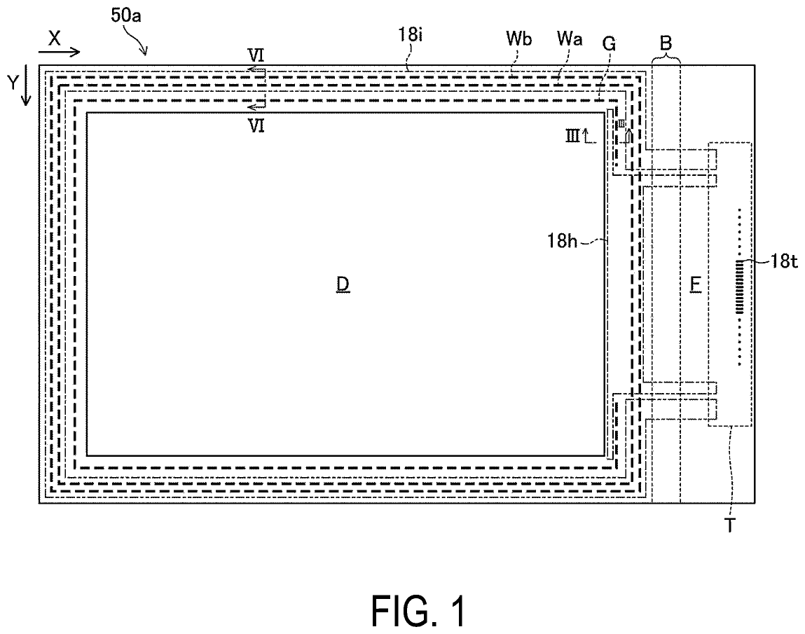

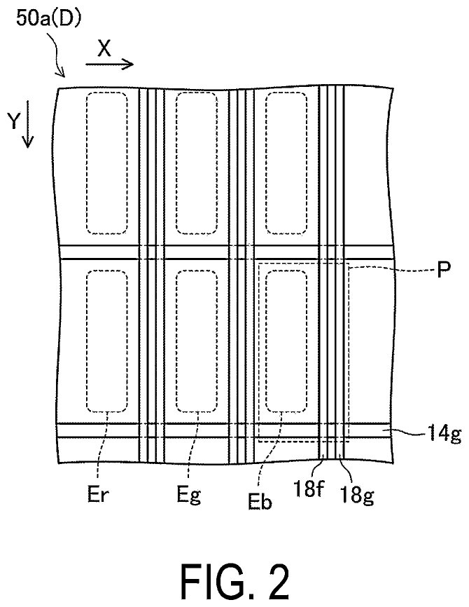

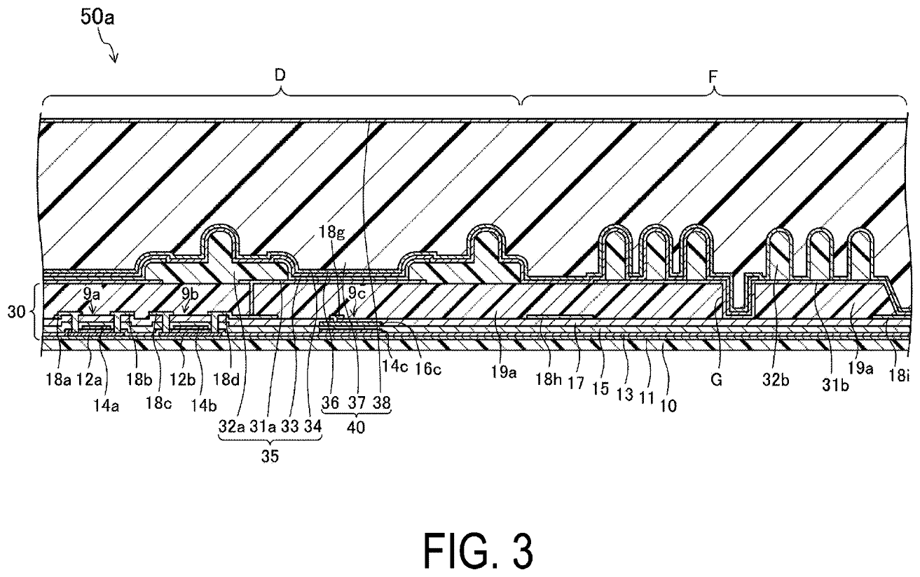

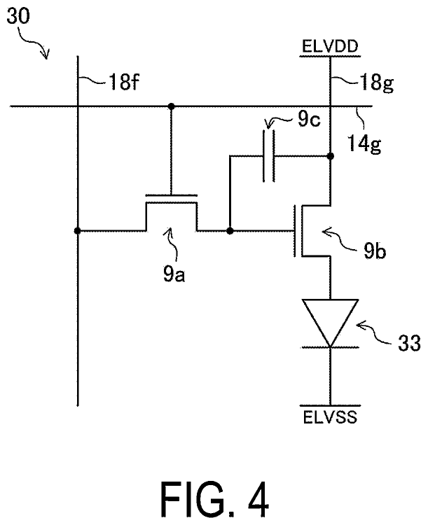

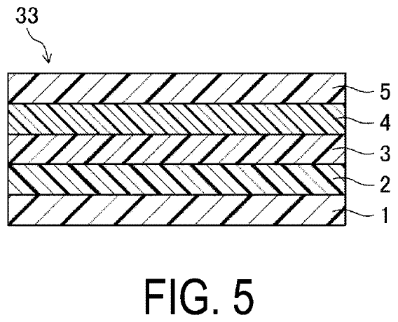

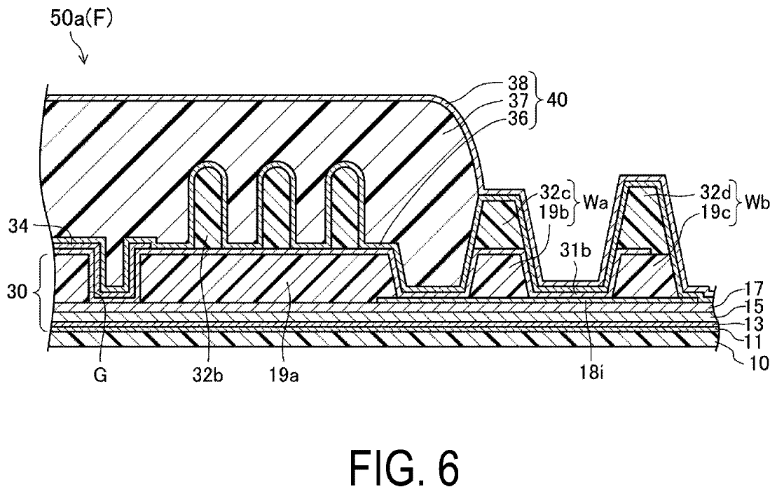

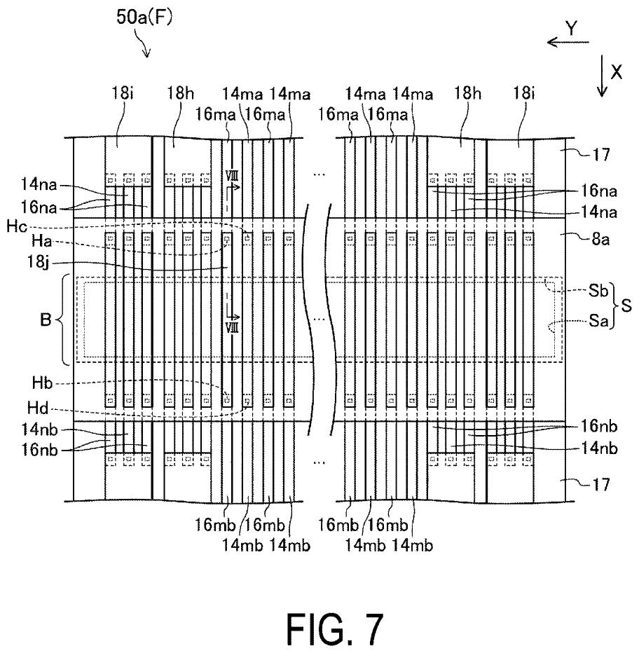

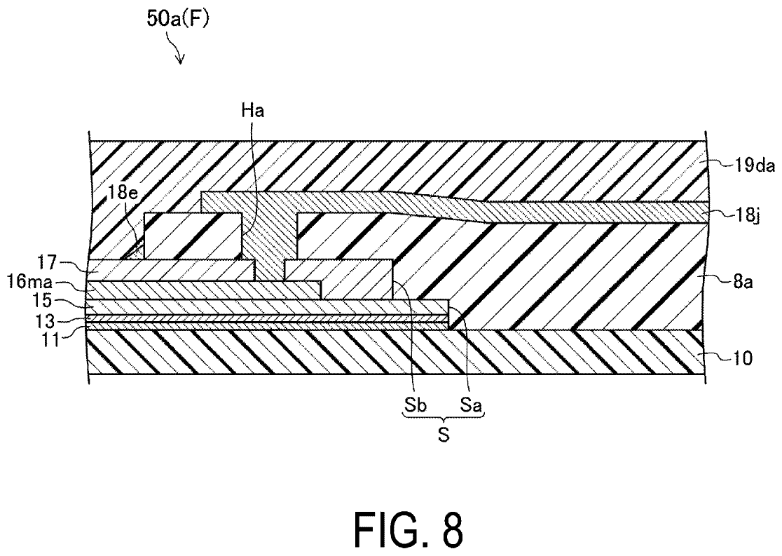

FIGS. 1 to 8 illustrate a first embodiment of a display device according to the disclosure. Note that, in each of the following embodiments, an organic EL display device including an organic EL element layer is exemplified as a display device including a light-emitting element layer. Here, FIG. 1 is a plan view illustrating a schematic configuration of an organic EL display device 50a according to the present embodiment. Further, FIG. 2 is a plan view of a display region D of the organic EL display device 50a. FIG. 3 is a cross-sectional view of the organic EL display device 50a taken along a line III-III in FIG. 1. FIG. 4 is an equivalent circuit diagram of a thin film transistor layer 30 included in the organic EL display device 50a. FIG. 5 is a cross-sectional view of an organic EL layer 33 included in the organic EL display device 50a. FIG. 6 is a cross-sectional view of a frame region F of the organic EL display device 50a taken along a line VI-VI in FIG. 1. Additionally, FIG. 7 is a plan view of the frame region F including a bending portion B of the organic EL display device 50a. Further, FIG. 8 is a cross-sectional view of the frame region F of the organic EL display device 50a taken along a line VIII-VIII in FIG. 7.

As illustrated in FIG. 1, the organic EL display device 50a includes, for example, the display region D provided in a rectangular shape and configured to display an image, and the frame region F provided in a frame-like shape surrounding the display region D. Note that in the present embodiment, the display region D having the rectangular shape is exemplified, but the rectangular shape includes a substantial rectangular shape such as a shape whose sides are arc-shaped, a shape whose corners are arc-shaped, and a shape in which a part of a side has a notch.

As illustrated in FIG. 2, a plurality of subpixels P are arrayed in a matrix in the display region D. In addition, in the display region D, for example, a subpixel P including a red light-emitting region Er configured to display a red color, a subpixel P including a green light-emitting region Eg configured to display a green color, and a subpixel P including a blue light-emitting region Eb configured to display a blue color are provided adjacent to one another, as illustrated in FIG. 2. Note that one pixel is configured by, for example, the three adjacent subpixels P including the red light-emitting region Er, the green light-emitting region Eg, and the blue light-emitting region Eb in the display region D.

A terminal portion T is provided at an end portion of the frame region F on the positive side in the X direction in FIG. 1 so as to extend in one direction (the Y direction in FIG. 1). Further, as illustrated in FIG. 1, in the frame region F, the bending portion B that can be bent, for example, by 180° (in a U-shape) with the Y direction in the figure as a bending axis is provided between the display region D and the terminal portion T so as to extend in one direction (the Y direction in the figure). Further, as illustrated in FIG. 1, a plurality of terminals 18t are arranged in the terminal portion T along a direction in which the terminal portion T extends (the Y direction in the figure). As illustrated in FIGS. 1, 3, and 6, in the frame region F, a trench G having a substantially C-shape in a plan view is provided in a flattening resin film 19a to be described below in such a manner as to pass through the flattening resin film 19a. Here, as illustrated in FIG. 1, in a plan view, the trench G is provided in the substantially C-shape so as to be open on a side of the terminal portion T.

As illustrated in FIGS. 3 and 6, the organic EL display device 50a includes a resin substrate 10, a thin film transistor (hereinafter, also referred to as “TFT”) layer 30 provided on the resin substrate 10, an organic EL element layer 35 provided as a light-emitting element layer on the TFT layer 30, and a sealing film 40 provided on the organic EL element layer 35.

The resin substrate 10 is formed of, for example, a polyimide resin.

As illustrated in FIG. 3, the TFT layer 30 includes a base coat film 11 provided on the resin substrate 10, a plurality of first TFTs 9a, a plurality of second TFTs 9b, and a plurality of capacitors 9c, which are provided on the base coat film 11, and the flattening resin film 19a provided on the first TFTs 9a, the second TFTs 9b, and the capacitors 9c. Here, as illustrated in FIG. 2, in the TFT layer 30, a plurality of gate lines 14g are provided to extend parallel to each other in the X direction in the figure. In addition, as illustrated in FIG. 2, in the TFT layer 30, a plurality of source lines 18f are provided to extend parallel to each other in the Y direction in the figure. In addition, as illustrated in FIG. 2, in the TFT layer 30, a plurality of power source lines 18g are provided to extend parallel to each other in the Y direction in the figure. Then, as illustrated in FIG. 2, the power source lines 18g are provided to be adjacent to the source lines 18f. Further, in the TFT layer 30, as illustrated in FIG. 4, the first TFT 9a, the second TFT 9b, and the capacitor 9c are disposed for each of the subpixels P. In the TFT layer 30, as illustrated in FIG. 3, on the resin substrate 10, the base coat film 11, a semiconductor layer such as a first semiconductor layer 12a, which will be described later, a gate insulating film 13, a gate metal layer such as a first gate electrode 14a, which will be described later, a first interlayer insulating film 15, an intermediate metal layer such as an upper conductive layer 16c, which will be described later, a second interlayer insulating film 17, a source metal layer (second metal layer) such as a first source electrode 18a, and the flattening resin film 19a are sequentially layered. Note that when the base coat film 11 and the gate insulating film 13 are a first inorganic insulating film, and the first interlayer insulating film 15 and the second interlayer insulating film 17 are a second inorganic insulating film, the gate metal layer is a first metal layer. On the other hand, when the base coat film 11, the gate insulating film 13, and the first interlayer insulating film 15 are the first inorganic insulating film, and the second interlayer insulating film 17 is the second inorganic insulating film, the intermediate metal layer is the first metal layer.

For example, each of the base coat film 11, the gate insulating film 13, the first interlayer insulating film 15, and the second interlayer insulating film 17 is composed of a single-layer film or a layered film of an inorganic insulating film of silicon nitride, silicon oxide, silicon oxynitride, or the like.

As illustrated in FIG. 4, the first TFT 9a is electrically connected to the corresponding gate line 14g and source line 18f in each of the subpixels P. In addition, the first TFT 9a includes the first semiconductor layer 12a, the gate insulating film 13, the first gate electrode 14a, the first interlayer insulating film 15, the second interlayer insulating film 17, and the first source electrode 18a and a first drain electrode 18b provided in order on the base coat film 11 as illustrated in FIG. 3. As illustrated in FIG. 3, the first semiconductor layer 12a is provided in an island shape on the base coat film 11 using, for example, a low-temperature polysilicon film, and includes a first channel region, a first source region, and a first drain region. In addition, the gate insulating film 13 covers the first semiconductor layer 12a as illustrated in FIG. 3. In addition, the first gate electrode 14a is provided on the gate insulating film 13 to overlap the first channel region of the first semiconductor layer 12a as illustrated in FIG. 3. In addition, the first interlayer insulating film 15 and the second interlayer insulating film 17 cover the first gate electrode 14a in order as illustrated in FIG. 3. In addition, the first source electrode 18a and the first drain electrode 18b are separated from each other on the second interlayer insulating film 17 as illustrated in FIG. 3. In addition, the first source electrode 18a and the first drain electrode 18b are electrically connected to the first source region and the first drain region of the first semiconductor layer 12a, respectively, via contact holes formed in a layered film including the gate insulating film 13, the first interlayer insulating film 15, and the second interlayer insulating film 17 as illustrated in FIG. 3.

The second TFT 9b is electrically connected to the corresponding first TFT 9a and power source line 18g in each of the subpixels P as illustrated in FIG. 4. In addition, the second TFT 9b includes a second semiconductor layer 12b, the gate insulating film 13, a second gate electrode 14b, the first interlayer insulating film 15, the second interlayer insulating film 17, and a second source electrode 18c and a second drain electrode 18d provided in order on the base coat film 11 as illustrated in FIG. 3. Here, similar to the first semiconductor layer 12a, as illustrated in FIG. 3, the second semiconductor layer 12b is provided in an island shape on the base coat film 11 using, for example, a low-temperature polysilicon film, and includes a second channel region, a second source region, and a second drain region. In addition, the gate insulating film 13 covers the second semiconductor layer 12b as illustrated in FIG. 3. In addition, the second gate electrode 14b is provided on the gate insulating film 13 to overlap the second channel region of the second semiconductor layer 12b as illustrated in FIG. 3. In addition, the first interlayer insulating film 15 and the second interlayer insulating film 17 cover the second gate electrode 14b in order as illustrated in FIG. 3. In addition, the second source electrode 18c and the second drain electrode 18d are separated from each other on the second interlayer insulating film 17 as illustrated in FIG. 3. In addition, the second source electrode 18c and the second drain electrode 18d are electrically connected to the second source region and the second drain region of the second semiconductor layer 12b, respectively, via contact holes formed in a layered film including the gate insulating film 13, the first interlayer insulating film 15, and the second interlayer insulating film 17 as illustrated in FIG. 3.

Note that the top-gate type first TFT 9a and second TFT 9b are exemplified in the present embodiment, but the first TFT 9a and the second TFT 9b may be bottom-gate type.

The capacitor 9c is electrically connected to the corresponding first TFT 9a and power source line 18g in each of the subpixels P as illustrated in FIG. 4. Here, as illustrated in FIG. 3, the capacitor 9c includes a lower conductive layer 14c formed in the same layer using the same material as the gate line 14g, the first gate electrode 14a, and the second gate electrode 14b, the first interlayer insulating film 15 provided so as to cover the lower conductive layer 14c, and the upper conductive layer 16c provided on the first interlayer insulating film 15 and overlapping the lower conductive layer 14c. Note that, as illustrated in FIG. 3, the upper conductive layer 16c is electrically connected to the power source line 18g via contact holes formed in the second interlayer insulating film 17.

The flattening resin film 19a has a flat surface in the display region D, and is made of, for example, an organic resin material such as a polyimide resin, an acrylic resin, or a polysiloxane resin.

The organic EL element layer 35 includes, as illustrated in FIG. 3, a plurality of first electrodes 31a, an edge cover 32a, a plurality of organic EL layers 33, and a second electrode 34 that are provided sequentially on the TFT layer 30.

The plurality of first electrodes 31a are provided in a matrix shape on the flattening resin film 19a to correspond to the plurality of subpixels P, as illustrated in FIG. 3. Here, as illustrated in FIG. 3, the first electrode 31a is electrically connected to the second drain electrode 18d of each of the second TFTs 9b via a contact hole formed in the flattening resin film 19a. Additionally, the first electrode 31a is provided as an anode electrode and has a function to inject holes into the organic EL layer 33. Additionally, the first electrode 31a is preferably formed of a material having a high work function to improve hole injection efficiency into the organic EL layer 33. Here, examples of a material constituting the first electrode 31a include a metal material such as silver (Ag), aluminum (Al), vanadium (V), cobalt (Co), nickel (Ni), tungsten (W), gold (Au), titanium (Ti), ruthenium (Ru), manganese (Mn), indium (In), ytterbium (Yb), lithium fluoride (LiF), platinum (Pt), palladium (Pd), molybdenum (Mo), iridium (Ir), and tin (Sn). Examples of the material of the first electrode 31a may also include an alloy such as astatine (At)/astatine oxide (AtO₂). Further, the material constituting the first electrode 31a may be, for example, an electrically conductive oxide such as tin oxide (SnO), zinc oxide (ZnO), indium tin oxide (ITO), and indium zinc oxide (IZO). Additionally, the first electrode 31a may be formed by layering a plurality of layers including any of the materials described above. Note that examples of compound materials having a high work function include indium tin oxide (ITO) and indium zinc oxide (IZO).

As illustrated in FIG. 3, the edge cover 32a is provided in a lattice pattern common to the plurality of subpixels P so as to cover peripheral end portions of the first electrodes 31a. Here, examples of a material of the edge cover 32a include organic resin materials such as a polyimide resin, an acrylic resin, a polysiloxane resin and the like.

As illustrated in FIG. 3, the plurality of organic EL layers 33 are disposed on the plurality of first electrodes 31a, respectively, and are provided, as a plurality of light-emitting function layers, in a matrix shape so as to correspond to the plurality of subpixels P. Here, as illustrated in FIG. 5, each of the organic EL layers 33 includes a hole injection layer 1, a hole transport layer 2, a light-emitting layer 3, an electron transport layer 4, and an electron injection layer 5, which are sequentially provided on the first electrode 31a.

The hole injection layer 1 is also referred to as an anode electrode buffer layer, and has a function to reduce an energy level difference between the first electrode 31a and the organic EL layer 33 and to improve hole injection efficiency from the first electrode 31a into the organic EL layer 33. Here, examples of materials constituting the hole injection layer 1 include triazole derivatives, oxadiazole derivatives, imidazole derivatives, polyarylalkane derivatives, pyrazoline derivatives, phenylenediamine derivatives, oxazole derivatives, styrylanthracene derivatives, fluorenone derivatives, hydrazone derivatives, and stilbene derivatives.

The hole transport layer 2 has a function to improve hole transport efficiency from the first electrode 31a to the organic EL layer 33. Here, examples of materials constituting the hole transport layer 2 include porphyrin derivatives, aromatic tertiary amine compounds, styrylamine derivatives, polyvinylcarbazole, poly-p-phenylenevinylene, polysilane, triazole derivatives, oxadiazole derivatives, imidazole derivatives, polyarylalkane derivatives, pyrazoline derivatives, pyrazolone derivatives, phenylenediamine derivatives, arylamine derivatives, amine-substituted chalcone derivatives, oxazole derivatives, styrylanthracene derivatives, fluorenone derivatives, hydrazone derivatives, stilbene derivatives, hydrogenated amorphous silicon, hydrogenated amorphous silicon carbide, zinc sulfide, and zinc selenide.

The light-emitting layer 3 is a region where, when a voltage is applied by the first electrode 31a and the second electrode 34, a hole and an electron are injected from the first electrode 31a and the second electrode 34, respectively, and the hole and the electron are recombined. Here, the light-emitting layer 3 is formed of a material having high luminous efficiency. Moreover, examples of materials constituting the light-emitting layer 3 include metal oxinoid compounds (8-hydroxyquinoline metal complexes), naphthalene derivatives, anthracene derivatives, diphenylethylene derivatives, vinyl acetone derivatives, triphenylamine derivatives, butadiene derivatives, coumarin derivatives, benzoxazole derivatives, oxadiazole derivatives, oxazole derivatives, benzimidazole derivatives, thiadiazole derivatives, benzothiazole derivatives, styryl derivatives, styrylamine derivatives, bisstyrylbenzene derivatives, trisstyrylbenzene derivatives, perylene derivatives, perinone derivatives, aminopyrene derivatives, pyridine derivatives, rhodamine derivatives, aquidine derivatives, phenoxazone, quinacridone derivatives, rubrene, poly-p-phenylenevinylene, and polysilane.

The electron transport layer 4 has a function of causing electrons to efficiently migrate to the light-emitting layer 3. Here, examples of materials constituting the electron transport layer 4 include oxadiazole derivatives, triazole derivatives, benzoquinone derivatives, naphthoquinone derivatives, anthraquinone derivatives, tetracyanoanthraquinodimethane derivatives, diphenoquinone derivatives, fluorenone derivatives, silole derivatives, and metal oxinoid compounds, as organic compounds.

The electron injection layer 5 functions to reduce an energy level difference between the second electrode 34 and the organic EL layer 33 to thereby improve the efficiency of electron injection into the organic EL layer 33 from the second electrode 34, and this function allows the drive voltage of the organic EL element to be reduced. Note that the electron injection layer 5 is also referred to as a cathode electrode buffer layer. Here, examples of materials constituting the electron injection layer 5 include inorganic alkaline compounds, such as lithium fluoride (LiF), magnesium fluoride (MgF₂), calcium fluoride (CaF₂), strontium fluoride (SrF₂), and barium fluoride (BaF₂); aluminum oxide (Al₂O₃); and strontium oxide (SrO).

The second electrode 34 is provided on the plurality of organic EL layers 33 so as to be common to the plurality of subpixels P, that is, the second electrode 34 is provided to cover each of organic EL layers 33 and the edge cover 32a, as illustrated in FIG. 3. Further, the second electrode 34 is provided as a cathode electrode and has a function to inject electrons into the organic EL layer 33. Further, the second electrode 34 is preferably formed of a material having a low work function to improve the efficiency of electron injection into the organic EL layer 33. Here, examples of a material constituting the second electrode 34 include silver (Ag), aluminum (Al), vanadium (V), calcium (Ca), titanium (Ti), yttrium (Y), sodium (Na), manganese (Mn), indium (In), magnesium (Mg), lithium (Li), ytterbium (Yb), and lithium fluoride (LiF). Further, the second electrode 34 may be formed of alloy such as magnesium (Mg)/copper (Cu), magnesium (Mg)/silver (Ag), sodium (Na)/potassium (K), astatine (At)/astatine oxide (AtO₂), lithium (Li)/aluminum (Al), lithium (Li)/calcium (Ca)/aluminum (Al), and lithium fluoride (LiF)/calcium (Ca)/aluminum (Al). Further, the second electrode 34 may be formed of an electrically conductive oxide such as tin oxide (SnO), zinc oxide (ZnO), indium tin oxide (ITO), and indium zinc oxide (IZO). Further, the second electrode 34 may be formed by layering a plurality of layers formed of any of the materials described above. Note that examples of materials having a low work function include magnesium (Mg), lithium (Li), lithium fluoride (LiF), magnesium (Mg)/copper (Cu), magnesium (Mg)/silver (Ag), sodium (Na)/potassium (K), lithium (Li)/aluminum (Al), lithium (Li)/calcium (Ca)/aluminum (Al), and lithium fluoride (LiF)/calcium (Ca)/aluminum (Al).

As illustrated in FIGS. 3 and 6, the sealing film 40 is provided covering the second electrode 34, and includes a first inorganic sealing film 36, an organic sealing film 37, and a second inorganic sealing film 38 sequentially layered on the second electrode 34, and has a function to protect the organic EL layer 33 of the organic EL element layer 35 from moisture and oxygen. Here, each of the first inorganic sealing film 36 and the second inorganic sealing film 38 is made of, for example, an inorganic insulating film such as a silicon nitride film, a silicon oxide film, a silicon oxynitride film or the like. Additionally, the organic sealing film 37 is made of, for example, an organic resin material such as an acrylic resin, an epoxy resin, a silicone resin, a polyurea resin, a parylene resin, a polyimide resin, a polyamide resin or the like.

Additionally, as illustrated in FIG. 1, the organic EL display device 50a includes, in the frame region F, a first dam wall Wa provided in a frame-like shape outside the trench G so as to surround the display region D and a second dam wall Wb provided in a frame-like shape around the first dam wall Wa.

As illustrated in FIG. 6, the first dam wall Wa includes a lower resin layer 19b formed in the same layer using the same material as the flattening resin film 19a, and an upper resin layer 32c that is provided on the lower resin layer 19b via a connection wiring line 31b, which will be described latter, and is formed in the same layer using the same material as the edge cover 32a. Here, the connection wiring line 31b is formed in the same layer using the same material as the first electrode 31a. Note that the first dam wall Wa is provided overlapping an outer peripheral end portion of the organic sealing film 37 of the sealing film 40, and is configured to suppress the spread of ink corresponding to the organic sealing film 37.

As illustrated in FIG. 6, the second dam wall Wb includes a lower resin layer 19c formed in the same layer using the same material as the flattening resin film 19a, and an upper resin layer 32d that is provided on the lower resin layer 19c via the connection wiring line 31b and is formed in the same layer using the same material as the edge cover 32a.

Further, as illustrated in FIG. 1, the organic EL display device 50a includes, in the frame region F, a first frame wiring line 18h. The first frame wiring line 18h extends widely in the X direction in the figure in an open portion of the trench G, both end portions thereof on the display region D side extends linearly, inside the trench G, along the positive side of the display region D in the X direction in the figure, and both end portions thereof on the terminal portion T side extend to the terminal portion T. Here, the first frame wiring line 18h is a power source voltage line that is electrically connected to the power source line 18g in the frame region F on the display region D side, and is configured such that a high power source voltage (ELVDD) is input in the terminal portion T. Note that the first frame wiring line 18h, and a second frame wiring line 18i and lead wiring lines 18j, which will be described later, are formed in the same layer using the same material as the first source electrode 18a, the second source electrode 18c, the first drain electrode 18b, the second drain electrode 18d, the source line 18f, and the power source line 18g.

In addition, as illustrated in FIG. 1, the organic EL display device 50a includes, in the frame region F, the second frame wiring line 18i provided in a substantially C-shape outside the trench G, with both end portions extending to the terminal portion T. Here, as illustrated in FIG. 6, the second frame wiring line 18i is a power source voltage line that is electrically connected to the second electrode 34 in the display region D via the connection wiring line 31b provided in the trench G, and is configured such that a low power source voltage (ELVSS) is input in the terminal portion T.

Further, as illustrated in FIGS. 3 and 6, the organic EL display device 50a includes a plurality of peripheral photo spacers 32b provided in island shapes so as to protrude upward at both edge portions of the trench G in the frame region F. Here, the peripheral photo spacer 32b is formed in the same layer using the same material as the edge cover 32a.

Further, as illustrated in FIGS. 7 and 8, the organic EL display device 50a includes, in the bending portion B in the frame region F, a filled resin film 8a provided in a belt shape to fill a slit S formed in a layered film including the base coat film 11, the gate insulating film 13, the first interlayer insulating film 15, and the second interlayer insulating film 17, a plurality of lead wiring lines 18j provided on the filled resin film 8a, and a protective resin film 19da provided so as to cover the lead wiring lines 18j.

As illustrated in FIGS. 7 and 8, the slit S is provided in a groove shape along a direction in which the bending portion B extends so as to pass through the base coat film 11, the gate insulating film 13, the first interlayer insulating film 15, and the second interlayer insulating film 17 and expose an upper face of the resin substrate 10. Here, as illustrated in FIGS. 7 and 8, the slit S includes a first slit Sa provided so as to pass through the base coat film 11, the gate insulating film 13, and the first interlayer insulating film 15, and a second slit Sb provided so as to pass through the second interlayer insulating film 17.

The filled resin film 8a is made of, for example, an organic resin material such as a polyimide resin, an acrylic resin, or a polysiloxane resin. Here, a film thickness of the filled resin film 8a (a film thickness on the resin substrate 10) is, for example, about 2 μm to 4 μm, and a film thickness on the second interlayer insulating film 17 is about 1 μm to 3 μm.

As illustrated in FIG. 7, the plurality of lead wiring lines 18j are provided so as to extend parallel to each other in a direction (the X direction in the figure) orthogonal to the direction in which the bending portion B extends (the Y direction in the figure). Here, a width of the lead wiring lines 18j is about 6 um, for example, and a distance between the lead wiring lines 18j is about 5 um, for example.

As illustrated in FIGS. 7 and 8, both end portions of one lead wiring line 18j of a pair of adjacent lead wiring lines 18j are electrically connected to a first lower wiring line 16maand a second lower wiring line 16mb via a first contact hole Ha and a second contact hole Hb formed in the layered film including the second interlayer insulating film 17 and the filled resin film 8a on the display region D side (the negative side in the X direction in FIG. 7) and the terminal portion T side (the positive side in the X direction in FIG. 7), respectively. Note that the first lower wiring line 16ma is formed in the same layer using the same material as the upper conductive layer 16c so as to extend toward the display region D side, and is electrically connected to, for example, the source line 18f located in the display region D. The second lower wiring line 16mb is formed in the same layer using the same material as the upper conductive layer 16c so as to extend toward the terminal portion T side, and is electrically connected to, for example, the terminal 18t in the terminal portion T.

As illustrated in FIG. 7, both end portions of another lead wiring line 18j of the pair of adjacent lead wiring lines 18j are electrically connected to a first lower wiring line 14ma and a second lower wiring line 14mb via a first contact hole Hc and a second contact hole Hd formed in the layered film including the first interlayer insulating film 15, the second interlayer insulating film 17, and the filled resin film 8a on the display region D side (the negative side in the X direction in FIG. 7) and the terminal portion T side (the positive side in the X direction in FIG. 7), respectively. Note that the first lower wiring line 14ma is formed in the same layer using the same material as the gate line 14g and the like so as to extend toward the display region D side, and is electrically connected to, for example, the source line 18f located in the display region D. The second lower wiring line 14mb is formed in the same layer using the same material as the gate line 14g and the like so as to extend toward the terminal portion T side, and is electrically connected to, for example, the terminal 18t in the terminal portion T.

Note that as illustrated in FIG. 7, the first frame wiring line 18h and the second frame wiring line 18i are switched to the plurality of lead wiring lines 18j in the bending portion B via a first lower wiring line 16na or 14na provided on the display region D side (the negative side in the X direction in FIG. 7), a second lower wiring line 16nb or 14nb provided on the terminal portion T side (the positive side in the X direction in FIG. 7), and corresponding contact holes. Here, the first lower wiring line 16na and the second lower wiring line 16nb are formed in the same layer using the same material as the upper conductive layer 16c. In addition, the first lower wiring line 14na and the second lower wiring line 14nb are formed in the same layer using the same material as the gate line 14g and the like.

The protective resin film 19da is formed in the same layer using the same material as the flattening resin film 19a.

In the organic EL display device 50a described above, in each of the subpixels P, a gate signal is input to the first TFT 9a via the gate line 14g to turn on the first TFT 9a, a data signal is written in the second gate electrode 14b of the second TFT 9b and the capacitor 9c via the source line 18f, and a current from the power source line 18g corresponding to a gate voltage of the second TFT 9b is supplied to the organic EL layer 33, whereby the light-emitting layer 3 of the organic EL layer 33 emits light to display an image. Further, in the organic EL display device 50a, even when the first TFT 9a is turned off, the gate voltage of the second TFT 9b is held by the capacitor 9c, and thus, light emission by the light-emitting layer 3 is maintained until a gate signal of the next frame is input.

Next, a method for manufacturing the organic EL display device 50a according to the present embodiment will be described. Here, the method of manufacturing the organic EL display device 50a according to the present embodiment includes a TFT layer forming step, an organic EL element layer forming step, and a sealing film forming step.

### TFT Layer Forming Step

First, for example, an inorganic insulating film (having a thickness of approximately 1000 nm) such as a silicon oxide film is formed on the resin substrate 10 formed on a glass substrate by a plasma chemical vapor deposition (CVD) method to form the base coat film 11.

Subsequently, for example, an amorphous silicon film (having a thickness of approximately 50 nm) is formed over the entire substrate on which the base coat film 11 is formed, by a plasma CVD method, the amorphous silicon film is crystallized by laser annealing or the like to form a semiconductor film of a polysilicon film, and then, the semiconductor film is patterned to form the first semiconductor layer 12a, the second semiconductor layer 12b, and the like.

Thereafter, an inorganic insulating film (having a thickness of approximately 100 nm) such as a silicon oxide film is formed over the entire substrate on which the first semiconductor layer 12a and the like are formed, for example, by plasma CVD method, to form the gate insulating film 13 to cover the first semiconductor layer 12a and the like.

Further, an aluminum film (having a thickness of approximately 350 nm), a molybdenum nitride film (having a thickness of approximately 50 nm), and the like are formed in order over the entire substrate on which the gate insulating film 13 is formed, for example, by a sputtering method, and then a metal layered film thereof is patterned to form the gate line 14g, the first gate electrode 14a, the second gate electrode 14b, the lower conductive layer 14c, the first lower wiring lines 14ma and 14na, the second lower wiring lines 14mb and 14nb, and the like.

Subsequently, impurity ions are doped into the first semiconductor layer 12a and the second semiconductor layer 12b using the first gate electrode 14a and second gate electrode 14b as masks, thereby forming the first channel region, the first source region, and the first drain region in the first semiconductor layer 12a, and forming the second channel region, the second source region, and the second drain region in the second semiconductor layer 12b.

Thereafter, an inorganic insulating film (having a thickness of approximately 100 nm) such as a silicon oxide film is formed, for example, by a plasma CVD method over the entire substrate on which the first channel region, the first source region, and the first drain region are formed in the first semiconductor layer 12a, and the second channel region, the second source region, and the second drain region are formed in the second semiconductor layer 12b, to form the first interlayer insulating film 15.

Further, an aluminum film (having a thickness of approximately 350 nm), a molybdenum nitride film (having a thickness of approximately 50 nm), and the like are sequentially formed over the entire substrate on which the first interlayer insulating film 15 is formed, for example, by a sputtering method, and then, a metal layered film thereof is patterned to form the upper conductive layer 16c, the first lower wiring lines 16ma and 16na, the second lower wiring lines 16mb and 16nb, and the like.

Subsequently, an inorganic insulating film (having a thickness of approximately 500 nm) such as a silicon oxide film is formed over the entire substrate on which the upper conductive layer 16c and the like are formed by, for example, a plasma CVD method to form the second interlayer insulating film 17.

Thereafter, the gate insulating film 13, the first interlayer insulating film 15, and the second interlayer insulating film 17 are patterned to form the contact holes and the like in the single-layer film of the second interlayer insulating film 17, the layered film including the first interlayer insulating film 15 and the second interlayer insulating film 17, and the layered film including the gate insulating film 13, the first interlayer insulating film 15, and the second interlayer insulating film 17.

Further, in the bending portion B, the second interlayer insulating film 17 is partially removed by dry etching to form the slit Sb, and then the layered film including the base coat film 11, the gate insulating film 13, and the first interlayer insulating film 15 is partially removed by dry etching to form the slit Sb, thereby forming the slit S.

Subsequently, for example, the entire substrate in which the slit S is formed is coated with a photosensitive polyimide resin, and then the coated film is subjected to pre-baking, exposing, developing, and post-baking to form the filled resin film 8a so as to fill the slit S in the bending portion B. At this time, upper portions of the first contact holes Ha and Hc and upper portions of the second contact holes Hb and Hd are formed in the filled resin film 8a, and then lower portions of the first contact holes Ha and Hc and lower portions of the second contact holes Hb and Hd are formed by removing the second interlayer insulating film 17 exposed from the upper portions of the first contact hole Ha and the second contact hole Hb, and the second interlayer insulating film 17 and the first interlayer insulating film 15 exposed from the upper portions of the first contact hole Hc and the second contact hole Hd.

Thereafter, a titanium film (having a thickness of approximately 30 nm), an aluminum film (having a thickness of approximately 300 nm), a titanium film (having a thickness of approximately 50 nm), and the like are sequentially formed by, for example, a sputtering method over the entire substrate on which the first contact holes Ha and Hc and the second contact holes Hb and Hd are formed, and then the metal layered film including those metal films is patterned to form the source line 18f, the power source line 18g, the first source electrode 18a, the first drain electrode 18b, the second source electrode 18c, the second drain electrode 18d, the first frame wiring line 18h, the second frame wiring line 18i, the lead wiring lines 18j, and the like.

Finally, the entire substrate on which the source line 18f and the like are formed is coated with a polyimide-based photosensitive resin film (having a thickness of approximately 2 μm) by, for example, a spin coating method or a slit coating method, and subsequently pre-baking, exposing, developing, and post-baking are performed on the coated film to form the flattening resin film 19a, the protective resin film 19da, and the like.

As described above, the TFT layer 30 can be formed.

### Organic EL Element Layer Forming Step

On the flattening resin film 19a of the TFT layer 30 formed in the TFT layer forming step described above, the first electrode 31a, the edge cover 32a, the organic EL layer 33 (the hole injection layer 1, the hole transport layer 2, the organic light-emitting layer 3, the electron transport layer 4, and the electron injection layer 5), and the second electrode 34 are formed by using a well-known method to form the organic EL element layer 35. Sealing Film Forming Step

First, an inorganic insulating film such as a silicon nitride film, a silicon oxide film, or a silicon oxynitride film is formed by the plasma CVD method using a mask, on the substrate surface on which the organic EL element layer 35 is formed at the above-described organic EL element layer forming step, to form the first inorganic sealing film 36.

Subsequently, an organic resin material such as an acrylic resin is discharged onto the surface of the substrate on which the first inorganic sealing film 36 is formed, inside the first dam wall Wa, for example, by an ink-jet method, thereby forming the organic sealing film 37.

Further, an inorganic insulating film such as a silicon nitride film, a silicon oxide film, or a silicon oxynitride film is formed on the substrate on which the organic sealing film 37 is formed by a plasma CVD method using a mask to form the second inorganic sealing film 38, thereby forming the sealing film 40.

Finally, after a protective sheet (not illustrated) is bonded to the surface of the substrate on which the sealing film 40 is formed, a laser beam is emitted thereto from the glass substrate side of the resin substrate 10 to peel off the glass substrate from a lower surface of the resin substrate 10, and then, a protective sheet (not illustrated) is bonded to the lower surface of the resin substrate 10 from which the glass substrate has been peeled off.

The organic EL display device 50a of the present embodiment can be manufactured as described above.

As described above, according to the organic EL display device 50a of the present embodiment, both end portions of one lead wiring line 18j of a pair of adjacent lead wiring lines 18j are electrically connected to the first lower wiring line 16ma and the second lower wiring line 16mb provided so as to extend toward the display region D side and the terminal portion T side via the first contact hole Ha and the second contact hole Hb, which are formed in the layered film including the second interlayer insulating film 17 and the filled resin film 8a, on the display region D side and the terminal portion T side, respectively. In addition, both end portions of the other lead wiring line 18j of the pair of adjacent lead wiring lines 18j are electrically connected to the first lower wiring line 14ma and the second lower wiring line 14mb provided so as to extend toward the display region D side and the terminal portion T side via the first contact hole Hc and the second contact hole Hd, which are formed in the layered film including the first interlayer insulating film 15, the second interlayer insulating film 17, and the filled resin film 8a, on the display region D side and the terminal portion T side, respectively. Therefore, even when residues 18e of the metal film serving as the lead wiring line 18j are generated at steps of both end portions of the belt-shaped filled resin film 8a, the residue 18e generated at the step of the filled resin film 8a is separated from the lead wiring line 18j provided on the upper face of the filled resin film 8a, and the second interlayer insulating film 17 is placed between the lead wiring line 18j and the first lower wiring line 16ma and the second lower wiring line 16mb, which are electrically connected to the lead wiring line 18j, and the layered film including the first interlayer insulating film 15 and the second interlayer insulating film 17 is placed between the lead wiring line 18j and the first lower wiring line 14ma and second lower wiring line 14mb, which are electrically connected to the lead wiring line 18j. Thus, conduction between the pair of adjacent lead wiring lines 18j via the residue 18e is suppressed, so that a short circuit between the adjacent wiring lines 18j in the bending portion B can be suppressed.

### Second Embodiment

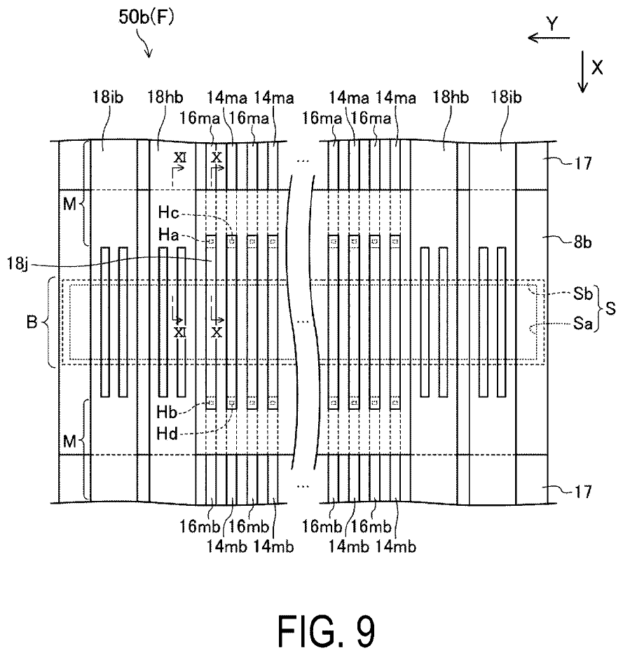

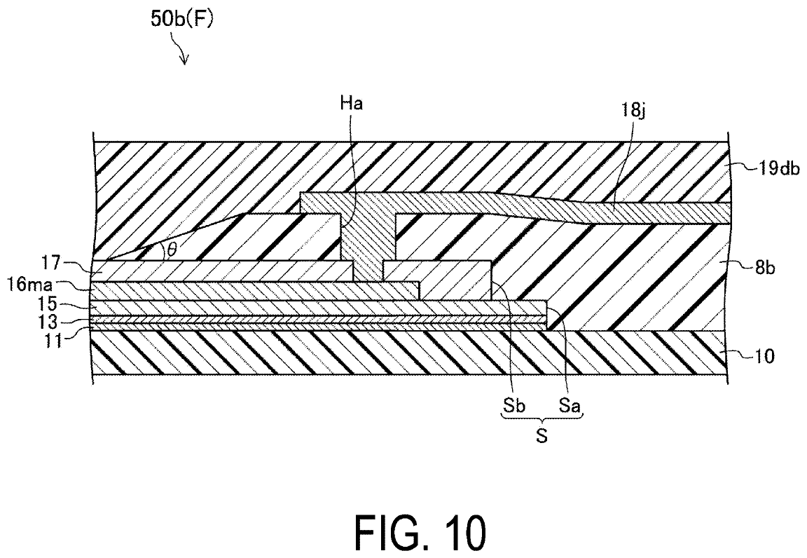

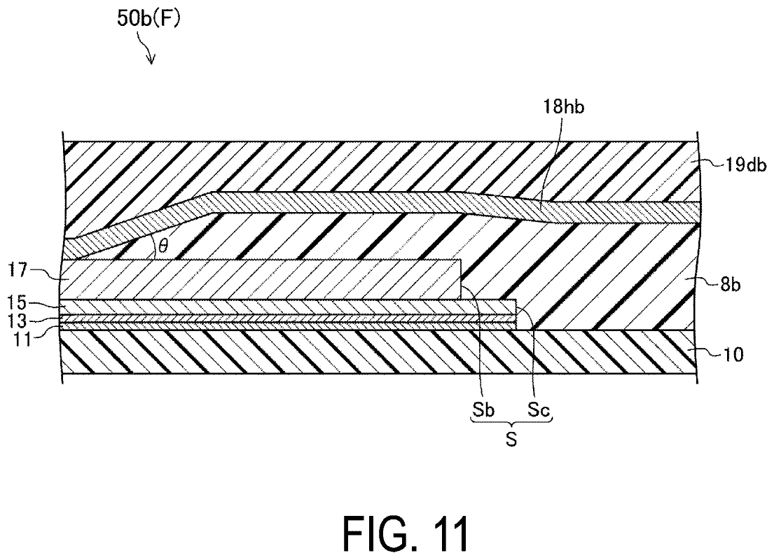

FIGS. 9 to 11 illustrate a second embodiment of a display device according to the disclosure. Here, FIG. 9 is a plan view of a frame region F including a bending portion B of an organic EL display device 50b of the present embodiment, and corresponds to FIG. 7 described in the first embodiment. Additionally, FIGS. 10 and 11 are cross-sectional views of the frame region F of the organic EL display device 50b taken along a line X-X and a line XI-XI in FIG. 9. Note that, in the following embodiments, the same portions as those in FIGS. 1 to 8 are denoted by the same reference numerals and signs, and a detailed description thereof will be omitted.

In the first embodiment, the organic EL display device 50a is exemplified in which the first frame wiring line 18h and the second frame wiring line 18i are also provided with the first lower wiring lines and the second lower wiring lines as the short-circuit countermeasure. In the present embodiment, the organic EL display device 50b is exemplified in which side surfaces of both side portions of a belt-shaped filled resin film 8b are gently sloped as a countermeasure for a short circuit between a first frame wiring line 18hb and a second frame wiring line 18ib.

Similar to the organic EL display device 50a of the first embodiment described above, the organic EL display device 50b is provided with a display region D in which an image is displayed and a frame region F provided around the display region D.

Further, similar to the organic EL display device 50a of the first embodiment described above, the organic EL display device 50b includes a resin substrate 10, a TFT layer 30 provided on the resin substrate 10, an organic EL element layer 35 provided on the TFT layer 30, and a sealing film 40 provided on the organic EL element layer 35.

Further, similar to the organic EL display device 50a of the first embodiment described above, the organic EL display device 50b includes, in the frame region F, a first dam wall Wa provided so as to surround the display region D, and a second dam wall Wb provided around the first dam wall Wa.

Further, similar to the organic EL display device 50a of the first embodiment described above, the organic EL display device 50b includes, in the frame region F, a first frame wiring line 18hb. The first frame wiring line 18hb extends widely in an open portion of a trench G, both end portions thereof on the display region D side extend linearly along one side of the display region D inside the trench G, and both end portions thereof on a terminal portion T side extend to the terminal portion T. Here, the first frame wiring line 18hb is a power source voltage line that is electrically connected to a power source line 18g in the frame region F on the display region D side, and is configured such that a high power source voltage (ELVDD) is input in the terminal portion T. Note that the first frame wiring line 18hb and the second frame wiring line 18ib, which will be described later, are formed in the same layer using the same material as a first source electrode 18a, a second source electrode 18c, a first drain electrode 18b, a second drain electrode 18d, a source line 18f, and the power source line 18g.

In addition, similar to the organic EL display device 50a of the first embodiment described above, the organic EL display device 50b includes, in the frame region F, the second frame wiring line 18ib provided in a substantially C-shape outside the trench G, with both end portions extending to the terminal portion T. Here, the second frame wiring line 18ib is a power source voltage line that is electrically connected to a second electrode 34 in the display region D via a connection wiring line 31b provided in the trench G, and is configured such that a low power source voltage (ELVSS) is input in the terminal portion T.

Further, similar to the organic EL display device 50a of the first embodiment described above, the organic EL display device 50b includes a plurality of peripheral photo spacers 32b provided in island shapes so as to protrude upward at both edge portions of the trench G in the frame region F.

Further, as illustrated in FIGS. 9 to 11, the organic EL display device 50b includes, in the bending portion B in the frame region F, a filled resin film 8b provided in a belt shape to fill a slit S formed in a layered film including a base coat film 11, a gate insulating film 13, a first interlayer insulating film 15, and a second interlayer insulating film 17, a plurality of lead wiring lines 18j provided on the filled resin film 8b, and a protective resin film 19db provided so as to cover the lead wiring lines 18j.

Similar to the organic EL display device 50a of the first embodiment described above, as illustrated in FIGS. 9 to 11, the slit S is provided in a groove shape along a direction in which the bending portion B extends so as to pass through the base coat film 11, the gate insulating film 13, the first interlayer insulating film 15 and the second interlayer insulating film 17 and expose an upper face of the resin substrate 10. Here, similar to the organic EL display device 50a of the first embodiment described above, as illustrated in FIGS. 9 to 11, the slit S includes a first slit Sa provided so as to pass through the base coat film 11, the gate insulating film 13, and the first interlayer insulating film 15, and a second slit Sb provided so as to pass through the second interlayer insulating film 17.

The filled resin film 8b is made of, for example, an organic resin material such as a polyimide resin, an acrylic resin, or a polysiloxane resin. Here, a film thickness of the filled resin film 8b (a film thickness on the resin substrate 10) is, for example, about 2 μm to 4 μm, and a film thickness on the second interlayer insulating film 17 is about 1 μm. The side surfaces of both side portions of the filled resin film 8b are inclined at an angle of 20° or less with respect to the upper face of the resin substrate 10. That is, in FIGS. 10 and 11, θ is equal to or less than 20°.

Similar to the organic EL display device 50a of the first embodiment described above, the plurality of lead wiring lines 18j are provided so as to extend parallel to each other in a direction (the X direction in the figure) orthogonal to the direction in which the bending portion B extends (the Y direction in the figure), as illustrated in FIG. 9.

Similar to the organic EL display device 50a of the first embodiment, as illustrated in FIGS. 9 and 10, both end portions of one lead wiring line 18j of a pair of adjacent lead wiring lines 18j are electrically connected to a first lower wiring line 16ma and a second lower wiring line 16mb via a first contact hole Ha and a second contact hole Hb formed in the layered film including the second interlayer insulating film 17 and the filled resin film 8b on the display region D side (the negative side in the X direction in FIG. 9) and the terminal portion T side (the positive side in the X direction in FIG. 9), respectively.

Similar to the organic EL display device 50a of the first embodiment, as illustrated in FIG. 9, both end portions of another lead wiring line 18j of the pair of adjacent lead wiring lines 18j are electrically connected to a first lower wiring line 14ma and a second lower wiring line 14mb via a first contact hole Hc and a second contact hole Hd formed in the layered film including the first interlayer insulating film 15, the second interlayer insulating film 17, and the filled resin film 8b on the display region D side (the negative side in the X direction in FIG. 9) and the terminal portion T side (the positive side in the X direction in FIG. 9), respectively.

Note that as illustrated in FIG. 9, the first frame wiring line 18hb and the second frame wiring line 18ib are divided into multiple branches in the bending portion B. As illustrated in FIG. 11, trunk portions M of the first frame wiring line 18hb and the second frame wiring line 18ib, which are not branched on both outer sides of the bending portion B, are provided on an upper face of the second interlayer insulating film 17, the side surfaces of both side portions of the filled resin film 8b, and an upper face of the filled resin film 8b.

Here, a width of the trunk portions M of the first frame wiring line 18hb and the second frame wiring line 18ib is about 20 μm, for example, and a distance between the trunk portions M is about 5 μm, for example.

The protective resin film 19db is formed in the same layer using the same material as the flattening resin film 19a.

Similar to the organic EL display device 50a of the first embodiment described above, the organic EL display device 50b described above is flexible and is configured to display an image by causing a light-emitting layer 3 of an organic EL layer 33 to appropriately emit light via a first TFT 9a and a second TFT 9b in each subpixel P.

The organic EL display device 50b of the present embodiment can be manufactured by omitting formation of the first lower wiring line 14na, the second lower wiring line 14nb, the first lower wiring line 16na, and the second lower wiring line 16nb, and changing a cross-sectional shape of the filled resin film 8a and planar shapes of the first frame wiring line 18h and the second frame wiring line 18i, in the TFT layer forming step of the method of manufacturing the organic EL display device 50a of the first embodiment. Here, tapered cross-sectional shapes of both end portions of the filled resin film 8b can be formed by half-exposure using, for example, a halftone mask, a gray-tone mask, or the like.

As described above, according to the organic EL display device 50b of the present embodiment, both end portions of one lead wiring line 18j of a pair of adjacent lead wiring lines 18j are electrically connected to the first lower wiring line 16ma and the second lower wiring line 16mb provided so as to extend toward the display region D side and the terminal portion T side via the first contact hole Ha and the second contact hole Hb, which are formed in the layered film including the second interlayer insulating film 17 and the filled resin film 8b, on the display region D side and the terminal portion T side, respectively. In addition, both end portions of the other lead wiring line 18j of the pair of adjacent lead wiring lines 18j are electrically connected to the first lower wiring line 14ma and the second lower wiring line 14mb provided so as to extend toward the display region D side and the terminal portion T side via the first contact hole Hc and the second contact hole Hd, which are formed in the layered film including the first interlayer insulating film 15, the second interlayer insulating film 17, and the filled resin film 8b, on the display region D side and the terminal portion T side, respectively. Therefore, even when residues 18e of the metal film serving as the lead wiring line 18j are generated at steps of both end portions of the belt-shaped filled resin film 8b, the residue 18e generated at the step of the filled resin film 8b is separated from the lead wiring line 18j provided on the upper face of the filled resin film 8b, and the second interlayer insulating film 17 is placed between the lead wiring line 18j and the first lower wiring line 16ma and the second lower wiring line 16mb, which are electrically connected to the lead wiring line 18j, and the layered film including the first interlayer insulating film 15 and the second interlayer insulating film 17 is placed between the lead wiring line 18j and the first lower wiring line 14ma and second lower wiring line 14mb, which are electrically connected to the lead wiring line 18j. Thus, conduction between the pair of adjacent lead wiring lines 18j via the residue 18e is suppressed, so that a short circuit between the adjacent wiring lines 18j in the bending portion B can be suppressed.

According to the organic EL display device 50b of the present embodiment, the trunk portions M of the first frame wiring line 18hb and the second frame wiring line 18ib are provided on the upper face of the second interlayer insulating film 17, the side surfaces of both side portions of the filled resin film 8b, and the upper face of the filled resin film 8b, and the side surfaces of both side portions of the filled resin film 8b are provided so as to be inclined at 20° or less with respect to the upper face of the resin substrate 10. With this configuration, it is possible to make it difficult to generate residues of the metal film to be the first frame wiring line 18hb and the second frame wiring line 18ib on both side portions of the filled resin film 8b, and thus a short circuit between the first frame wiring line 18hb and the second frame wiring line 18ib can be suppressed.

### Third Embodiment

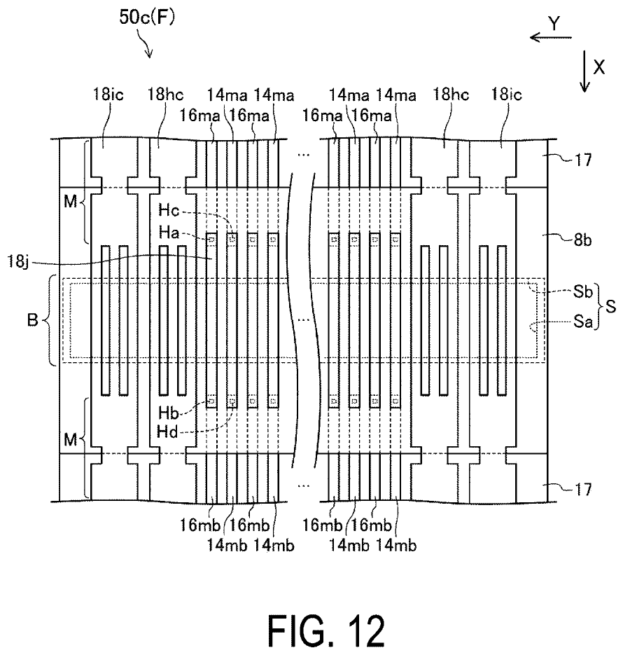

FIG. 12 illustrates a third embodiment of the display device according to the disclosure. Here, FIG. 12 is a plan view of a frame region F including a bending portion B of an organic EL display device 50c of the present embodiment, and corresponds to FIG. 7 described in the first embodiment.

In the second embodiment, the organic EL display device 50b is exemplified in which the side surfaces of both side portions of the belt-shaped filled resin film 8b are gently sloped as the countermeasure for a short circuit between the first frame wiring line 18hb and the second frame wiring line 18ib. In the present embodiment, the organic EL display device 50c is exemplified in which side surfaces of both side portions of a belt-shaped filled resin film 8b are gently sloped and trunk portions M of a first frame wiring line 18hc and a second frame wiring line 18ic are constricted at both the side ends of the filled resin film 8b, as a countermeasure for a short-circuit between the first frame wiring line 18hc and the second frame wiring line 18ic.

Similar to the organic EL display device 50a of the first embodiment described above, the organic EL display device 50c is provided with a display region D in which an image is displayed and a frame region F provided around the display region D.

Further, similar to the organic EL display device 50a of the first embodiment described above, the organic EL display device 50c includes a resin substrate 10, a TFT layer 30 provided on the resin substrate 10, an organic EL element layer 35 provided on the TFT layer 30, and a sealing film 40 provided on the organic EL element layer 35.

Additionally, similar to the organic EL display device 50a of the first embodiment described above, the organic EL display device 50c includes, in the frame region F, a first dam wall Wa provided so as to surround the display region D, and a second dam wall Wb provided around the first dam wall Wa.

Further, similar to the organic EL display device 50a of the first embodiment described above, the organic EL display device 50c includes, in the frame region F, the first frame wiring line 18hc. The first frame wiring line 18hc extends widely in an open portion of a trench G, both end portions thereof on the display region D side extend linearly along one side of the display region D inside the trench G, and both end portions thereof on a terminal portion T side extend to the terminal portion T. Here, the first frame wiring line 18hc is a power source voltage line that is electrically connected to a power source line 18g in the frame region F on the display region D side, and is configured such that a high power source voltage (ELVDD) is input in the terminal portion T. Note that the first frame wiring line 18hc and the second frame wiring line 18ic, which will be described later, are formed in the same layer using the same material as a first source electrode 18a, a second source electrode 18c, a first drain electrode 18b, a second drain electrode 18d, a source line 18f, and the power source line 18g.

In addition, similar to the organic EL display device 50a of the first embodiment described above, the organic EL display device 50c includes, in the frame region F, the second frame wiring line 18ic provided in a substantially C-shape outside the trench G, with both end portions extending to the terminal portion T. Here, the second frame wiring line 18ic is a power source voltage line that is electrically connected to a second electrode 34 in the display region D via a connection wiring line 31b provided in the trench G, and is configured such that a low power source voltage (ELVSS) is input in the terminal portion T.

Further, similar to the organic EL display device 50a of the first embodiment described above, the organic EL display device 50c includes a plurality of peripheral photo spacers 32b provided in island shapes so as to protrude upward at both edge portions of the trench G in the frame region F.

Further, as illustrated in FIG. 12, the organic EL display device 50c includes, in the bending portion B in the frame region F, a filled resin film 8b provided in a belt shape to fill a slit S formed in a layered film including a base coat film 11, a gate insulating film 13, a first interlayer insulating film 15, and a second interlayer insulating film 17, a plurality of lead wiring lines 18j provided on the filled resin film 8b, and a protective resin film 19db (not illustrated) provided so as to cover the lead wiring lines 18j.

Similar to the organic EL display device 50a of the first embodiment described above, the plurality of lead wiring lines 18j are provided so as to extend parallel to each other in a direction (the X direction in the figure) orthogonal to the direction in which the bending portion B extends (the Y direction in the figure), as illustrated in FIG. 12.

Similar to the organic EL display device 50a of the first embodiment, as illustrated in FIG. 12, both end portions of one lead wiring line 18j of a pair of adjacent lead wiring lines 18j are electrically connected to a first lower wiring line 16ma and a second lower wiring line 16mb via a first contact hole Ha and a second contact hole Hb formed in the layered film including the second interlayer insulating film 17 and the filled resin film 8b on the display region D side (the negative side in the X direction in the figure) and the terminal portion T side (the positive side in the X direction in the figure), respectively.

Similar to the organic EL display device 50a of the first embodiment, as illustrated in FIG. 12, both end portions of another lead wiring line 18j of the pair of adjacent lead wiring lines 18j are electrically connected to a first lower wiring line 14ma and a second lower wiring line 14mb via a first contact hole Hc and a second contact hole Hd formed in the layered film including the first interlayer insulating film 15, the second interlayer insulating film 17, and the filled resin film 8b on the display region D side (the negative side in the X direction in the figure) and the terminal portion T side (the positive side in the X direction in the figure), respectively.

Note that as illustrated in FIG. 12, the first frame wiring line 18hc and the second frame wiring line 18ic are divided into multiple branches in the bending portion B. Similar to the organic EL display device 50b of the second embodiment, the trunk portions M of the first frame wiring line 18hc and the second frame wiring line 18ic, which are not branched on both outer sides of the bending portion B, are provided on an upper face of the second interlayer insulating film 17, side surfaces of both side portions of the filled resin film 8b, and an upper face of the filled resin film 8b. Here, a width (at non-constricted portions) of the trunk portions M of the first frame wiring line 18hc and the second frame wiring line 18ic is, for example, about 20 μm and a distance between the trunk portions M (at the non-constricted portions) is, for example, about 5 μm. Note that the trunk portions M of the first frame wiring line 18hc and the second frame wiring line 18ic are provided so as to be constricted at both side ends of the filled resin film 8b, and a width of constricted portions are, for example, about 5 μm, and a distance between the trunk portions M at the constricted portions is, for example, about 20 μm.

Similar to the organic EL display device 50a of the first embodiment described above, the organic EL display device 50c described above is flexible and is configured to display an image by causing a light-emitting layer 3 of an organic EL layer 33 to appropriately emit light via a first TFT 9a and a second TFT 9b in each subpixel P.

The organic EL display device 50c of the present embodiment can be manufactured by omitting formation of the first lower wiring line 14na, the second lower wiring line 14nb, the first lower wiring line 16na, and the second lower wiring line 16nb, and changing a cross-sectional shape of the filled resin film 8a and planar shapes of the first frame wiring line 18h and the second frame wiring line 18i, in the TFT layer forming step of the method of manufacturing the organic EL display device 50a of the first embodiment.

As described above, according to the organic EL display device 50c of the present embodiment, both end portions of one lead wiring line 18j of a pair of adjacent lead wiring lines 18j are electrically connected to the first lower wiring line 16ma and the second lower wiring line 16mb provided so as to extend toward the display region D side and the terminal portion T side via the first contact hole Ha and the second contact hole Hb, which are formed in the layered film including the second interlayer insulating film 17 and the filled resin film 8b, on the display region D side and the terminal portion T side, respectively. In addition, both end portions of the other lead wiring line 18j of the pair of adjacent lead wiring lines 18j are electrically connected to the first lower wiring line 14ma and the second lower wiring line 14mb provided so as to extend toward the display region D side and the terminal portion T side via the first contact hole Hc and the second contact hole Hd, which are formed in the layered film including the first interlayer insulating film 15, the second interlayer insulating film 17, and the filled resin film 8b, on the display region D side and the terminal portion T side, respectively. Therefore, even when residues 18e of the metal film serving as the lead wiring line 18j are generated at steps of both end portions of the belt-shaped filled resin film 8b, the residue 18e generated at the step of the filled resin film 8b is separated from the lead wiring line 18j provided on the upper face of the filled resin film 8b, and the second interlayer insulating film 17 is placed between the lead wiring line 18j and the first lower wiring line 16ma and the second lower wiring line 16mb, which are electrically connected to the lead wiring line 18j, and the layered film including the first interlayer insulating film 15 and the second interlayer insulating film 17 is placed between the lead wiring line 18j and the first lower wiring line 14ma and second lower wiring line 14mb, which are electrically connected to the lead wiring line 18j. Thus, conduction between the pair of adjacent lead wiring lines 18j via the residue 18e is suppressed, so that a short circuit between the adjacent wiring lines 18j in the bending portion B can be suppressed.

According to the organic EL display device 50c of the present embodiment, the trunk portions M of the first frame wiring line 18hc and the second frame wiring line 18ic are provided on the upper face of the second interlayer insulating film 17, the side surfaces of both side portions of the filled resin film 8b, and the upper face of the filled resin film 8b, and the side surfaces of both side portions of the filled resin film 8b are provided so as to be inclined at 20° or less with respect to an upper face of the resin substrate 10. Further, the trunk portions M of the first frame wiring line 18hc and the second frame wiring line 18ic are provided so as to be constricted at both side ends of the filled resin film 8b. With this configuration, it is possible to make it difficult to generate residues of the metal film to be the first frame wiring line 18hc and the second frame wiring line 18ic on both side portions of the filled resin film 8b, and the first frame wiring line 18hc and the second frame wiring line 18ic are further separated by the constrictions at both side ends of the filled resin film 8b, and thus a short circuit between the first frame wiring line 18hc and the second frame wiring line 18ic can be further suppressed.

### Fourth Embodiment

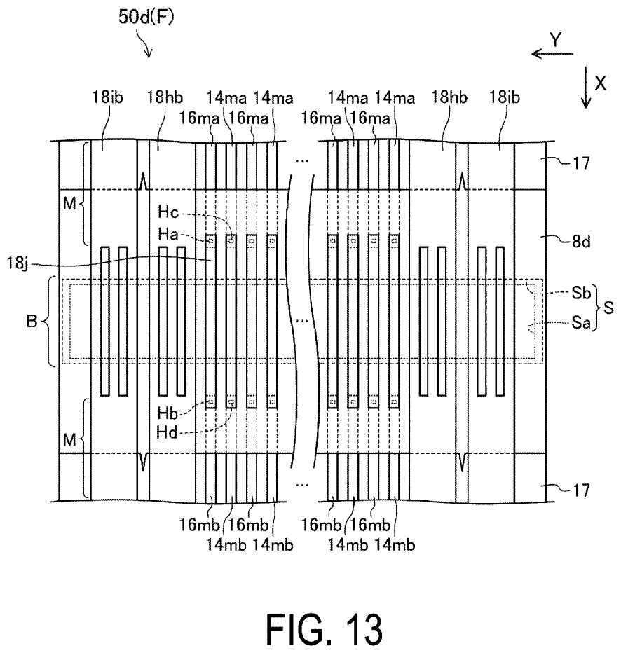

FIG. 13 illustrates a fourth embodiment of the display device according to the disclosure. Here, FIG. 13 is a plan view of a frame region F including a bending portion B of an organic EL display device 50d of the present embodiment, and corresponds to FIG. 7 described in the first embodiment.

In the third embodiment, the organic EL display device 50c is exemplified in which the side surfaces of both side portions of the belt-shaped filled resin film 8b are gently sloped, and the trunk portions M of the first frame wiring line 18hc and the second frame wiring line 18ic are constricted at both side ends of the filled resin film 8b, as the countermeasure for a short circuit between the first frame wiring line 18hc and the second frame wiring line 18ic. In the present embodiment, the organic EL display device 50d is exemplified in which side surfaces of both side portions of a belt-shaped filled resin film 8d are gently sloped, and both ends of the filled resin film 8d protrude outward between a first frame wiring line 18hb and a second frame wiring line 18ib, as a countermeasure for a short circuit between the first frame wiring line 18hb and the second frame wiring line 18ib.

Similar to the organic EL display device 50a of the first embodiment described above, the organic EL display device 50d is provided with a display region D in which an image is displayed and a frame region F provided around the display region D.

Further, similar to the organic EL display device 50a of the first embodiment described above, the organic EL display device 50d includes a resin substrate 10, a TFT layer 30 provided on the resin substrate 10, an organic EL element layer 35 provided on the TFT layer 30, and a sealing film 40 provided on the organic EL element layer 35.

Additionally, similar to the organic EL display device 50a of the first embodiment described above, the organic EL display device 50d includes, in the frame region F, a first dam wall Wa provided so as to surround the display region D, and a second dam wall Wb provided around the first dam wall Wa.

Further, similar to the organic EL display device 50b of the second embodiment described above, the organic EL display device 50d includes, in the frame region F, the first frame wiring line 18hb. The first frame wiring line 18hb extends widely in an open portion of a trench G, both end portions thereof on the display region D side extend linearly along one side of the display region D inside the trench G, and both end portions thereof on a terminal portion T side extend to the terminal portion T.

In addition, similar to the organic EL display device 50b of the second embodiment described above, the organic EL display device 50d includes, in the frame region F, the second frame wiring line 18ib provided in a substantially C-shape outside the trench G, with both end portions extending to the terminal portion T.

Further, similar to the organic EL display device 50a of the first embodiment described above, the organic EL display device 50d includes a plurality of peripheral photo spacers 32b provided in island shapes so as to protrude upward at both edge portions of the trench G in the frame region F.

Further, as illustrated in FIG. 13, the organic EL display device 50d includes, in the bending portion B in the frame region F, a filled resin film 8d provided in a belt shape to fill a slit S formed in a layered film including a base coat film 11, a gate insulating film 13, a first interlayer insulating film 15, and a second interlayer insulating film 17, a plurality of lead wiring lines 18j provided on the filled resin film 8d, and a protective resin film 19db (not illustrated) provided so as to cover the lead wiring lines 18j.

The filled resin film 8d is made of, for example, an organic resin material such as a polyimide resin, an acrylic resin, or a polysiloxane resin. Here, a film thickness of the filled resin film 8d (a film thickness on the resin substrate 10) is, for example, about 2 μm to 4 μm, and a film thickness on the second interlayer insulating film 17 is about 1 μm. The side surfaces of both side portions of the filled resin film 8d are inclined at an angle of 20° or less with respect to an upper face of the resin substrate 10. Further, as illustrated in FIG. 13, both side ends of the filled resin film 8d are provided so as to protrude outward in a plan view between the trunk portion M of the first frame wiring line 18hb and the trunk portion M of the second frame wiring line 18ib.

Similar to the organic EL display device 50a of the first embodiment described above, the plurality of lead wiring lines 18j are provided so as to extend parallel to each other in a direction (the X direction in the figure) orthogonal to the direction in which the bending portion B extends (the Y direction in the figure), as illustrated in FIG. 13.

Similar to the organic EL display device 50a of the first embodiment, as illustrated in FIG. 13, both end portions of one lead wiring line 18j of a pair of adjacent lead wiring lines 18j are electrically connected to a first lower wiring line 16ma and a second lower wiring line 16mb via a first contact hole Ha and a second contact hole Hb formed in the layered film including the second interlayer insulating film 17 and the filled resin film 8d on the display region D side (the negative side in the X direction in the figure) and the terminal portion T side (the positive side in the X direction in the figure), respectively.

Similar to the organic EL display device 50a of the first embodiment, as illustrated in FIG. 13, both end portions of another lead wiring line 18j of the pair of adjacent lead wiring lines 18j are electrically connected to a first lower wiring line 14ma and a second lower wiring line 14mb via a first contact hole Hc and a second contact hole Hd formed in the layered film including the first interlayer insulating film 15, the second interlayer insulating film 17, and the filled resin film 8d on the display region D side (the negative side in the X direction in the figure) and the terminal portion T side (the positive side in the X direction in the figure), respectively.

Note that as illustrated in FIG. 13, the first frame wiring line 18hb and the second frame wiring line 18ib are divided into multiple branches in the bending portion B. Similar to the organic EL display device 50b of the second embodiment, the trunk portions M of the first frame wiring line 18hb and the second frame wiring line 18ib, which are not branched on both outer sides of the bending portion B, are provided on an upper face of the second interlayer insulating film 17, side surfaces of both side portions of the filled resin film 8d, and an upper face of the filled resin film 8d.

Similar to the organic EL display device 50a of the first embodiment described above, the organic EL display device 50d described above is flexible and is configured to display an image by causing a light-emitting layer 3 of an organic EL layer 33 to appropriately emit light via a first TFT 9a and a second TFT 9b in each subpixel P.

The organic EL display device 50d of the present embodiment can be manufactured by omitting formation of the first lower wiring line 14na, the second lower wiring line 14nb, the first lower wiring line 16na, and the second lower wiring line 16nb, and changing a cross-sectional shape and a planar shape of the filled resin film 8a and planar shapes of the first frame wiring line 18h and the second frame wiring line 18i, in the TFT layer forming step of the method of manufacturing the organic EL display device 50a of the first embodiment.

As described above, according to the organic EL display device 50d of the present embodiment, both end portions of one lead wiring line 18j of a pair of adjacent lead wiring lines 18j are electrically connected to the first lower wiring line 16ma and the second lower wiring line 16mb provided so as to extend toward the display region D side and the terminal portion T side via the first contact hole Ha and the second contact hole Hb, which are formed in the layered film including the second interlayer insulating film 17 and the filled resin film 8d, on the display region D side and the terminal portion T side, respectively. In addition, both end portions of the other lead wiring line 18j of the pair of adjacent lead wiring lines 18j are electrically connected to the first lower wiring line 14ma and the second lower wiring line 14mb provided so as to extend toward the display region D side and the terminal portion T side via the first contact hole Hc and the second contact hole Hd, which are formed in the layered film including the first interlayer insulating film 15, the second interlayer insulating film 17, and the filled resin film 8d, on the display region D side and the terminal portion T side, respectively. Therefore, even when residues 18e of the metal film serving as the lead wiring line 18j are generated at steps of both end portions of the belt-shaped filled resin film 8d, the residue 18e generated at the step of the filled resin film 8d is separated from the lead wiring line 18j provided on the upper face of the filled resin film 8d, and the second interlayer insulating film 17 is placed between the lead wiring line 18j and the first lower wiring line 16ma and the second lower wiring line 16mb, which are electrically connected to the lead wiring line 18j, and the layered film including the first interlayer insulating film 15 and the second interlayer insulating film 17 is placed between the lead wiring line 18j and the first lower wiring line 14ma and second lower wiring line 14mb, which are electrically connected to the lead wiring line 18j. Thus, conduction between the pair of adjacent lead wiring lines 18j via the residue 18e is suppressed, so that a short circuit between the adjacent wiring lines 18j in the bending portion B can be suppressed.

According to the organic EL display device 50d of the present embodiment, the trunk portions M of the first frame wiring line 18hb and the second frame wiring line 18ib are provided on the upper face of the second interlayer insulating film 17, the side surfaces of both side portions of the filled resin film 8d, and the upper face of the filled resin film 8d, and the side surfaces of both side portions of the filled resin film 8d are provided so as to be inclined at 20° or less with respect to the upper face of the resin substrate 10. Further, both side ends of the filled resin film 8d are provided so as to protrude outward between the trunk portion M of the first frame wiring line 18hb and the trunk portion M of the second frame wiring line 18ib. With this configuration, it is possible to make it difficult to generate residues of the metal film to be the first frame wiring line 18hb and the second frame wiring line 18ib on both side portions of the filled resin film 8d, and thus a short circuit between the first frame wiring line 18hb and the second frame wiring line 18ib can be further suppressed.

### Other Embodiments

In each of the embodiments described above, the organic EL display device is exemplified in which the first lower wiring line and the second lower wiring line are electrically connected to each of the lead wiring lines 18j. However, the disclosure can also be applied to an organic EL display device in which the first lower wiring line and the second lower wiring line are electrically connected to at least one of the plurality of lead wiring lines 18j.

Although the organic EL layer having a five-layer structure including the hole injection layer, the hole transport layer, the light-emitting layer, the electron transport layer, and the electron injection layer has been exemplified in each of the embodiments described above, the organic EL layer may have a three-layer structure including a hole injection-cum-transport layer, a light-emitting layer, and an electron transport-cum-injection layer, for example.

In each of the embodiments described above, the organic EL display device including the first electrode as an anode electrode and the second electrode as a cathode electrode is exemplified. The disclosure is also applicable to an organic EL display device in which the layered structure of the organic EL layer is reversed with the first electrode being a cathode electrode and the second electrode being an anode electrode.

Although the organic EL display device in which the electrode of the TFT connected to the first electrode serves as the drain electrode has been exemplified in each of the embodiments described above, the disclosure is also applicable to an organic EL display device in which the electrode of the TFT connected to the first electrode is referred to as the source electrode.

In each of the embodiments described above, the organic EL display device is exemplified as a display device. The disclosure can also be applied to a display device including a plurality of light-emitting elements driven by a current, for example, to a display device including quantum dot light-emitting diodes (QLEDs), which are a light-emitting element using a quantum dot-containing layer.

### Industrial Applicability

As described above, the disclosure is useful for a flexible display device.

1. A display device comprising:
a resin substrate;
a thin film transistor layer provided on the resin substrate and including a first inorganic insulating film, a first metal layer, a second inorganic insulating film, a second metal layer, and a flattening resin film layered in order; and
a light-emitting element layer provided on the thin film transistor layer and including a plurality of first electrodes, a plurality of light-emitting function layers, and a common second electrode layered in order, corresponding to a plurality of subpixels constituting a display region,
wherein a frame region is provided around the display region,
a terminal portion is provided in an end portion of the frame region,
a bending portion is provided between the display region and the terminal portion and extends in one direction,
a slit is provided in the first inorganic insulating film and the second inorganic insulating film in the bending portion and extends along an extending direction of the bending portion,
a filled resin film is provided in the bending portion in a belt shape and fills the slit,
on the filled resin film, a plurality of lead wiring lines are provided in the same layer using the same material as the second metal layer and extends parallel to each other in a direction intersecting the extending direction of the bending portion, and
at least one of the plurality of lead wiring lines is electrically connected to a first lower wiring line and a second lower wiring line provided in the same layer using the same material as the first metal layer and extending to a display region side and a terminal portion side via a first contact hole and a second contact hole formed in a layered film including the second inorganic insulating film and the filled resin film on the display region side and the terminal portion side, respectively,
the plurality of lead wiring lines include a power source voltage line having trunk portions on both side portions of the filled resin film,
side surfaces of both the side portions of the filled resin film are inclined with respect to an upper face of the resin substrate by protruding the filled resin film on a second inorganic insulating film side, and
the trunk portions are provided on an upper face of the second inorganic insulating film, the side surfaces of the filled resin film, and an upper face of the filled resin film.

2. (canceled)

3. The display device according to claim 1,
wherein the trunk portions are provided in a pair adjacent to other trunk portions, and the trunk portions and the other trunk portions are constricted at both side ends of the filled resin film.

4. The display device according to claim 1,
wherein the trunk portions are provided in a pair adjacent to the other trunk portions, and
both the side ends of the filled resin film protrude outward between the pair of the trunk portions and the other trunk portions adjacent to each other.

5. The display device according to claim 1,
wherein the side surfaces of both the side portions of the filled resin film are inclined at an angle of 20° or less with respect to the upper face of the resin substrate.

6. (canceled)

7. The display device according to claim 1,
wherein the first inorganic insulating film is a base coat film and a gate insulating film, and
the second inorganic insulating film is a first interlayer insulating film and a second interlayer insulating film.

8. The display device according to claim 1,
wherein the first inorganic insulating film is a base coat film, a gate insulating film, and a first interlayer insulating film, and
the second inorganic insulating film is a second interlayer insulating film.

9. The display device according to claim 1,
wherein the slit passes through the first inorganic insulating film and the second inorganic insulating film.

10. The display device according to claim 1, the display device comprising:
a sealing film provided on the light-emitting element layer.

11. The display device according to claim 1,
wherein each of the plurality of light-emitting function layers is an organic electroluminescence layer.

12. A display device comprising:
a resin substrate;
a thin film transistor layer provided on the resin substrate and including a first inorganic insulating film, a first metal layer, a second inorganic insulating film, a second metal layer, and a flattening resin film layered in order; and
a light-emitting element layer provided on the thin film transistor layer and including a plurality of first electrodes, a plurality of light-emitting function layers, and a common second electrode layered in order, corresponding to a plurality of subpixels constituting a display region,
wherein a frame region is provided around the display region,
a terminal portion is provided in an end portion of the frame region,
a bending portion is provided between the display region and the terminal portion and extends in one direction,
a slit is provided in the first inorganic insulating film and the second inorganic insulating film in the bending portion and extends along an extending direction of the bending portion,
a filled resin film is provided in the bending portion in a belt shape and fills the slit,
on the filled resin film, a plurality of lead wiring lines are provided in the same layer using the same material as the second metal layer and extends parallel to each other in a direction intersecting the extending direction of the bending portion,
at least one of the plurality of lead wiring lines is electrically connected to a first lower wiring line and a second lower wiring line provided in the same layer using the same material as the first metal layer and extending to a display region side and a terminal portion side via a first contact hole and a second contact hole formed in a layered film including the second inorganic insulating film and the filled resin film on the display region side and the terminal portion side, respectively, and
a protective resin film formed in the same layer using the same material as the flattening resin film is provided on the plurality of lead wiring lines.

13. The display device according to claim 12,
wherein the plurality of lead wiring lines include a power source voltage line having trunk portions on both side portions of the filled resin film,
side surfaces of both the side portions of the filled resin film are inclined with respect to an upper face of the resin substrate by protruding the filled resin film on a second inorganic insulating film side, and
the trunk portions are provided on an upper face of the second inorganic insulating film, the side surfaces of the filled resin film, and an upper face of the filled resin film.

14. The display device according to claim 13,
wherein the trunk portions are provided in a pair adjacent to other trunk portions, and the trunk portions and the other trunk portions are constricted at both side ends of the filled resin film.

15. The display device according to claim 13,
wherein the trunk portions are provided in a pair adjacent to the other trunk portions, and
both the side ends of the filled resin film protrude outward between the pair of the trunk portions and the other trunk portions adjacent to each other.

16. The display device according to claim 13,
wherein the side surfaces of both the side portions of the filled resin film are inclined at an angle of 20° or less with respect to the upper face of the resin substrate.

17. The display device according to claim 12,
wherein the first inorganic insulating film is a base coat film and a gate insulating film, and
the second inorganic insulating film is a first interlayer insulating film and a second interlayer insulating film.

18. The display device according to claim 12,
wherein the first inorganic insulating film is a base coat film, a gate insulating film, and a first interlayer insulating film, and
the second inorganic insulating film is a second interlayer insulating film.

19. The display device according to claim 12,
wherein the slit passes through the first inorganic insulating film and the second inorganic insulating film.

20. The display device according to claim 12, the display device comprising:
a sealing film provided on the light-emitting element layer.

21. The display device according to claim 12,
wherein each of the plurality of light-emitting function layers is an organic electroluminescence layer.
